(19) United States
(12) Patent Application Publication
(10) Pub. No.: US 2023/0331928 A1
(43) Pub. Date: Oct. 19, 2023

(54) HYPERBRANCHED POLYMER, METHOD OF MAKING, AND CURABLE COMPOSITION INCLUDING THE SAME

(71) Applicant: 3M INNOVATIVE PROPERTIES COMPANY, St. Paul, MN (US)

(72) Inventors: Claire Hartmann-Thompson, Lake Elmo, MN (US); Nicholas C. Erickson, St. Paul, MN (US); Stephen M. Menke, Eagan, MN (US)

(21) Appl. No.: 18/027,256

(22) PCT Filed: Aug. 10, 2021
(86) PCT No.: PCT/IB2021/057387

§ 371 Date: Mar. 20, 2023

Related U.S. Application Data
(60) Provisional application No. 63/081,135, filed on Sep. 21, 2020.

(51) Int. Cl. C08G 83/00; C08G 77/12; C08G 77/20; C08G 77/08; H10K 59/80

(52) U.S. Cl. CPC C08G 83/005; C08G 77/12; C08G 77/20; C08G 77/08; H10K 59/873

(57) ABSTRACT

A hyperbranched polymer comprising a reaction product of a hydrosilylation reaction catalyst and components a) and b), which combined contain 15 to 60 percent by weight of aromatic carbon atoms. Component a) is at least one first organosilane independently having p vinyl groups and consisting of C, H, Si, and optionally O atoms, wherein each p is independently an integer greater than or equal to 2. Component b) is at least one second organosilane independently having q Si—H groups and consisting of C, H, Si, and optionally O atoms, wherein each q is independently an integer greater than or equal to 2. p/q is at least 3.1. A curable composition comprises the hyperbranched polymer and a crosslinker system. An at least partially reaction product of the curable composition and N electronic articles including the same are also disclosed.

### TECHNICAL FIELD

The present disclosure broadly relates to hyperbranched organosilane polymers, compositions containing them, and methods of making the same.

### BACKGROUND

Increasingly, optical devices are becoming more complicated and involve more and more functional layers. As light travels through the layers of the optical device, the light can be altered by the layers in a wide variety of ways. For example, light can be reflected, refracted or absorbed. In many cases, layers that are included in optical devices for non-optical reasons adversely affect the optical properties. For example, if a support layer is included that is not optically clear, the absorption of light by the non-optically clear support layer can adversely affect the light transmission of the entire device.

One common difficulty with multi-layer optical devices is that when layers of differing refractive indices are adjacent to each other, refraction of light can occur at their interface. In some devices this refraction of light is desirable, but in other devices the refraction is undesirable. Also, at angles of incidence higher than a critical angle, light can be reflected at the interface between two layers. In order to minimize or eliminate this refraction or reflection of light at the interface between two layers, efforts have been made to minimize the difference in refractive index between the two layers that form the interface.

However, as a wider range of materials have been employed within optical devices, the matching of refractive indices has become increasingly difficult. Organic polymer films and coatings, which are frequently used in optical devices, have a limited range of refractive indices. As higher refractive index materials are increasingly used in optical devices, it has become increasingly difficult to prepare organic compositions that have suitable optical properties, such as desirable refractive indices and optical clarity, and yet retain desirable features such as, for example, processability and flexibility.

For applications in which the optical device is incorporated into an electronic device (e.g., a cell phone or a tablet computer) that is it is necessary to use materials that have a low dielectric constant so that they do not adversely affect performance of the device.

### SUMMARY

Many materials having high refractive index also typically have high dielectric constants. Conversely, materials with low dielectric constants typically have low refractive indexes that are unsuitable for use in optical electronic devices such as OLEDs, for example.

Advantageously, the present disclosure provides materials and methods capable of achieving a balance of dielectric constant and refractive index that are suitable for such applications (e.g., OLEDs).

In one aspect, the present disclosure provides a hyperbranched polymer comprising a reaction product of components:
a) at least one first organosilane independently having p vinyl groups and consisting of C, H, Si, and optionally O atoms, wherein each p is independently an integer greater than or equal to 2;
b) at least one second organosilane independently having q Si—H groups and consisting of C, H, Si, and optionally O atoms, wherein each q is independently an integer greater than or equal to 2; and
c) at least one hydrosilylation reaction catalyst,
wherein p/q is at least 3.1, and
wherein components a) and b) combined contain 15 to 60 percent by weight of aromatic carbon atoms.

In another aspect, the present disclosure provides, a method of making a hyperbranched polymer, the method comprising combining components:
a) at least one first organosilane independently having p vinyl groups and consisting of C, H, Si, and optionally O atoms, wherein each p is independently an integer greater than or equal to 2;
b) at least one second organosilane independently having q Si—H groups and consisting of C, H, Si, and optionally O atoms, wherein each q is independently an integer greater than or equal to 2; and
c) at least one hydrosilylation reaction catalyst,
wherein p/q is at least 3.1, and
wherein components a) and b) combined contain 15 to 60 percent by weight of aromatic carbon atoms.

In yet another aspect, the present disclosure provides an at least partially cured curable composition according to the present disclosure.

In yet another aspect, the present disclosure provides an electronic article comprising an at least partially cured curable composition disposed on an optical electronic component.

As used herein:
the term “aromatic carbon atom” refers to a carbon atom in a carbon-based aromatic ring (e.g., benzene, naphthalene, biphenyl) or group (e.g., phenyl, naphthyl, biphenylyl);
the term “hydrocarbyl group” refers to a monovalent radical composed of carbon and hydrogen atoms;
the term “hydrocarbylene group” refers to a divalent radical composed of carbon and hydrogen atoms;
the term “hydrocarbon radical” refers to a monovalent or polyvalent radical composed of carbon and hydrogen atoms;
the term “hyperbranched polymer” refers to a macromolecule that is densely branched (but typically not as densely as a dendrimer) and that is typically obtained in one synthetic step (in contrast to a dendrimer);
the term “organosilane” refers to a compound containing at least one Si—C bond;
the group “Si—H” refers to a silicon atom having but a single H bonded to it. The remaining three bonds are to carbon, and/or oxygen, preferably carbon and/or oxygen.
the term “vinyl” refers to the group —CH═CH₂.

Features and advantages of the present disclosure will be further understood upon consideration of the detailed description as well as the appended claims.

### BRIEF DESCRIPTION OF THE DRAWINGS

FIG. 1 is a schematic side view of an electronic article 100.

It should be understood that numerous other modifications and embodiments can be devised by those skilled in the art, which fall within the scope and spirit of the principles of the disclosure. The FIGURES may not be drawn to scale.

### DETAILED DESCRIPTION

Hyperbranched polymers according to the present disclosure can be prepared by a hydrosilylation reaction of at least one first organosilane with at least one second organosilane facilitated by at least one hydrosilylation catalyst.

Useful first organosilanes may independently have p vinyl groups and consist of C, H, Si, and optionally O atoms. In some embodiments, useful first organosilanes have from 4 to 50 carbon atoms (e.g., 4 to 50, 4 to 36, 4 to 18, or 4 to 12 carbon atoms), 2 to 10 silicon atoms (e.g., 2 to 10, 2 to 6, or 2 to 4 silicon atoms), and 0 to 9 oxygen atoms (e.g., 0 to 9, 0 to 6, 0 to 4, 0 to 2, or 0 to 1 oxygen atom). If O is present, it is preferably in an ether linkage (i.e., C—O—C). Each p is independently an integer greater than or equal to 2 (e.g., 3, 4, 5, 6, 7, or 8). In some embodiments, useful first organosilanes consist of C, H, and Si atoms. In some embodiments, useful first organosilanes include aromatic carbon atoms, while in other embodiments they do not.

In some embodiments, useful first organosilane(s) is/are independently represented by the formula

Si(OSiR²₂CH═CH₂)_{b}(R²CH═CH₂)_{c}(R¹)_{d}

Each R² is independently a direct bond (i.e., a covalent bond) or a hydrocarbylene group having 1 to 12 carbon atoms. Examples include methylene, ethylene, propane-1,3-diyl, propane-1,2-diyl, butane-1,4-diyl, butane-1,3-diyl, pentane-1,5-diyl, pentane-1,4-diyl, hexane-1,6-diyl, octan-1,8-diyl, decan-1,10-diyl, dodecan-1,12-diyl, 1,4-phenylene, and 1,8-biphenylene.

Each R¹ is independently a hydrocarbyl group having from 1 to 12 carbon atoms (e.g., methyl, ethyl, n-propyl, isopropyl, n-butyl, sec-butyl, n-pentyl, n-hexyl, phenyl, biphenylyl, and alkyl-substituted phenyl). In some embodiments, R¹ comprises an optionally substituted phenyl group (e.g., phenyl, biphenylyl, tolyl, xylyl, methoxyphenyl).

b is an integer from 0 to 4 (i.e., 0, 1, 2, 3, or 4), c is an integer from 0 to 4 (i.e., 0, 1, 2, 3, or 4), and d is an integer from 0 to 2 (i.e., 0, 1, or 2), with the proviso that b+c≥2 (in some embodiments, b+c≥3) and b+c+d=4.

Exemplary first organosilanes include: 1,3-divinyl-1,3-diphenyl-1,3-dimethyldisiloxane; 1,1,3,3-tetraphenyl-1,3-divinyldisiloxane; 1,4-bis(vinyldimethylsilyl)benzene; 1,5-divinyl-3-phenylpentamethyltrisiloxane; 1,3-divinyl-1,1,3,3,-tetramethyldisiloxane; 1,4-divinyl-1,1,4,4-tetramethyl-1,4-disilabutane; divinyldimethylsilane; 1,5-divinyl-3,3-diphenyl-1,1,5,5-tetramethyltrisiloxane; 1,3-divinyltetrakis(trimethylsiloxy)disiloxane; 1,5-divinylhexamethyltrisiloxane; bis(divinyl)-terminated polydimethylsiloxane; 1,3-divinyltetraethoxydisiloxane; 1,3-divinyl-1,3-dimethyl-1,3-dimethoxydisiloxane; trivinylmethoxysilane; 1,3,5-trivinyl-1,3,5-trimethylcyclotrisiloxane; 1,3,5-trivinyl-1,1,3,5,5-pentamethyltrisiloxane; 1,3,5,7-tetravinyl-1,3,5,7-tetramethylcyclotetrasiloxane; 1,1,3,3-tetravinyldimethyldisiloxane; tetravinylsilane; tetraallylsilane; 1,3,5,7,9-pentavinyl-1,3,5,7,9-pentamethylcyclopentasiloxane; hexavinyldisiloxane; and 1,3,5,7,9,11-hexavinylhexamethylcyclohexasiloxane. The foregoing vinyl compounds are available from commercial suppliers such as, for example, Gelest, Inc., Morrisville, Pennsylvania, and/or can be synthesized by known methods. Of these tetravinylsilane, tetraallylsilane, and 1,1,3,3-tetraphenyl-1,3-divinyldisiloxane are preferred in some embodiments.

Useful second organosilanes may independently have q Si—H groups and consist of C, H, Si, and optionally O atoms. In some embodiments, useful second organosilanes have from 4 to 50 carbon atoms (e.g., 4 to 50, 4 to 36, 4 to 18, or 4 to 12 carbon atoms), 2 to 10 silicon atoms (e.g., 2 to 10, 2 to 6, or 2 to 4 silicon atoms), and 0 to 9 oxygen atoms (e.g., 0 to 9, 0 to 6, 0 to 4, 0 to 2, or 0 to 1 oxygen atom). If 0 is present, Z is preferably a single oxygen atom or the oxygen is present in an ether linkage. Each q is independently an integer greater than or equal to 2 (e.g., 3, 4, 5, 6, 7, or 8). In some embodiments, useful second organosilanes consist of C, H, and Si atoms. In some embodiments, useful second organosilanes include aromatic carbon atoms, while in other embodiments they do not.

In some embodiments, useful second organosilane(s) is/are independently represented by the formula

Z(SiR¹₂H)ₐ

Each Z is independently an a-valent radical composed of Si and O, or Z is an a-valent radical composed of C, H, and optionally O.

Each Z independently has from 1 to 12 carbon atoms. For example, Z may be a carbon atom (tetravalent), an oxygen atom (divalent), methylene (divalent), ethan-1,2-diyl (divalent), propan-1,3-diyl (divalent), CH₃CH₃(CH₂—)₃ (trivalent). In some embodiments Z is a phenylene group.

Each R¹ is independently as defined previously hereinabove.

a is an integer from 2 to 8 (i.e., 2, 3, 4, 5, 6, 7, or 8).

Exemplary second organosilanes include: 1,1,4,4-tetramethyl-1,4-disilabutane; 1,4-bis(dimethylsilyl)benzene; 1,2-bis(dimethylsilyl)benzene; tris(dimethylsiloxy)phenylsilane; 1,1,3,3-tetramethyldisiloxane; 1,3-disilapropane; bis[(p-dimethylsilyl)phenyl] ether; 1,3,5,7,9-pentamethylcyclopentasiloxane; 1,1,3,3,5,5-hexamethyltrisiloxane; 1,3,5,7-tetramethylcyclotetrasiloxane; 1,3-diphenyltetrakis(dimethylsiloxy)disiloxane; tris(dimethylsiloxy)ethoxysilane; methyltris(dimethylsiloxy)silane; 1,1,1,3,3,5,5-heptamethyltrisiloxane; 1,1,3,3-tetraisopropyldisiloxane; 4,4′-bis(dimethylsilyl)biphenyl; and tetrakis(dimethylsiloxy)silane. The foregoing Si—H group-containing compounds are available from commercial suppliers such as, for example, Gelest, Inc. and/or can be synthesized by known methods. Of these, 1,1,4,4-tetramethyl-1,4-disilabutane, 1,4-bis(dimethylsilyl)benzene, bis[(p-dimethylsilyl)phenyl]ether, tetrakis(dimethylsiloxy)silane are preferred in some embodiments.

In some embodiments, aromatic carbon atoms are present in either or both of components a) (i.e., at least one first organosilane) and b) (i.e., at least one second organosilane). In some embodiments, aromatic carbon atoms are present in both of components a) and b).

Hydrosilylation, also called catalytic hydrosilylation, describes the addition of Si—H bonds across unsaturated bonds. When hydrosilylation is used to synthesize hyperbranched polymers according to the present disclosure, vinyl group(s) on the first organosilane react with Si—H group(s) on the second organosilane. The stoichiometry of the reactants is adjusted such that there is at least a 3.1 equivalent excess of vinyl groups relative to Si—H groups; that is, p/q is at least 3.1. This ensures that the hyperbranched polymer will have pendant vinyl groups, and helps limit unwanted crosslinking of the polymer during its synthesis. In some embodiments the ratio p/q is at least 3.5, 4, 4.5, or even at least 5.

The hydrosilylation reaction is typically catalyzed by a platinum catalyst, and generally heat is applied to effect the curing reaction. In this reaction, the Si—H adds across the double bond to form new C—H and Si—C bonds. This process in described, for example, in PCT Publication No. WO 2000/068336 (Ko et al.), and PCT Publication Nos. WO 2004/111151 and WO 2006/003853 (Nakamura).

Useful hydrosilylation catalysts may include thermal catalysts and/or photocatalysts. Of these, photocatalysts may be preferred due to prolonged storage stability and ease of handling Exemplary thermal catalysts include platinum complexes such as H₂PtCl₆ (Speier's catalyst); organometallic platinum complexes such as, for example, a coordination complex of platinum and a divinyldisloxane (Karstedt's catalyst); and chloridotris(triphenylphosphine)rhodium(I) (Wilkinson's catalyst),

Useful platinum photocatalysts are disclosed, for example, in U.S. Pat. No. 7,192,795 (Boardman et al.) and references cited therein. Certain preferred platinum photocatalysts are selected from the group consisting of Pt(II) β-diketonate complexes (such as those disclosed in U.S. Pat. No. 5,145,886 (Oxman et al.)), (η5-cyclopentadienyptri(σ-aliphatic)platinum complexes (such as those disclosed in U.S. Pat. No. 4,916,169 (Boardman et al.) and U.S. Pat. No. 4,510,094 (Drahnak)), and C₇₋₂₀-aromatic substituted (η5-cyclopentadienyptri(σ-aliphatic)platinum complexes (such as those disclosed in U.S. Pat. No. 6,150,546 (Butts)). Hydrosilylation photocatalysts are activated by exposure to actinic radiation, typically ultraviolet light, for example, according to known methods.

The amount of hydrosilylation catalyst may be any effective amount. In some embodiments, the amount of hydrosilylation catalyst is in an amount of from about 0.5 to about 30 parts of platinum per million parts of the total weight of Si—H and vinyl group-containing compounds combined, although greater and lesser amounts may also be used.

To make the hyperbranched polymer the first and second organosilanes are combined with the hydrosilylation catalyst under conditions such that hydrosilylation occurs. In some cases, mere mixing is sufficient. In other cases, heating and/or irradiation with ultraviolet light may be helpful.

In order to increase the refractive index of the hyperbranched polymer, components a) and b) combined contain 15 to 60 percent by weight of aromatic carbon atoms, preferably 30 to 60 percent, more preferably 40 to 60 percent. The aromatic carbon atoms may be in either or both of components a) and b).

In at least some embodiments, curable compositions and their corresponding cured reaction products have a refractive index of from 1.50 to 1.60, although higher and lower values are permissible.

Likewise, in at least some embodiments, curable compositions and their corresponding cured reaction products have a dielectric constant of less than 3.0 at a measurement frequency of one megahertz.

Hyperbranched polymers according to the present disclosure are useful, for example, for preparing curable compositions. The curable compositions comprise the hyperbranched polymer and an effective amount of a crosslinker system.

The crosslinker system includes a third organosilane which may be the same as, or different than, the second organosilane having at least two (in some cases at least three or even at least four) Si—H groups and a hydrosilylation reaction catalyst. Suitable third organosilanes are enumerated hereinabove in the description of the second organosilane. The third organosilanes should have at least two Si—H groups per molecule (preferably 2, 3, or 4), and are preferably of relatively low molecular weight so as to maintain/impart low viscosity to the curable composition. Examples of suitable third organosilanes include: tetrakis(dimethylsiloxy)silane; and 1,1,4,4-tetramethyl-1,4-disilabutane.

The crosslinker system may be added in any amount, but is typically present in an amount of about weight percent or less, based on the total weight of the curable composition. Highest amounts will typically be used when the curing system includes a third organosilane, while lowest amounts (e.g., less than 5 weight percent) will typically be used when the curing system comprises free-radical (photo) initiators.

While the curable composition may contain other ingredients such as for example, organic solvent, nanoparticle fillers, ultraviolet light absorbers, adhesion promoters, wetting agents, and antioxidants, it is preferably free of them.

Useful hydrosilylation catalysts are described hereinabove; however in the curable compositions or the present disclosure, free-radical initiators (thermal and/or photoinitiators) may be used instead or in addition. Photoinitiators may be Type I and/or Type II photoinitiators, preferably Type I.

Exemplary thermal free-radical initiators may include peroxides (e.g., benzoyl peroxide) and azo compounds (e.g., azobisisobutyronitrile), typically in an amount of less than about 10 percent by weight, more typically less than 5 percent by weight, although this is not a requirement.

Exemplary photoinitiators (i.e., photoactivated free-radical initiators) include α-cleavage photoinitiators (Type I) such as benzoin and its derivatives such as α-methylbenzoin; α-phenylbenzoin; α-allylbenzoin; α-benzylbenzoin; benzoin ethers such as benzil dimethyl ketal (available as IRGACURE 651 from Ciba Specialty Chemicals, Tarrytown, New York), benzoin methyl ether, benzoin ethyl ether, benzoin n-butyl ether; acetophenone and its derivatives such as 2-hydroxy-2-methyl-1-phenyl-1-propanone, and 1-hydroxycyclohexyl phenyl ketone; and acylphosphines, acylphosphine oxides, and acylphosphinates such as diphenyl-2,4,6-trimethylbenzoylphosphine oxide, and ethyl (2,4,6-trimethylbenzoyl) phenyl phosphinate. One useful photoinitiator, a difunctional α-hydroxyketone, is available as ESACURE ONE from IGM Resins, Waalwijk, The Netherlands. Other exemplary photoinitiators include Type II photoinitiators such as anthraquinones (e.g., anthraquinone, 2-ethylanthraquinone, 1-chloroanthraquinone, 1,4-dimethylanthraquinone, 1-methoxyanthraquinone) and benzophenone and its derivatives (e.g., phenoxybenzophenone, phenylbenzophenone).

The crosslinker system may be present in any amount, typically less than about 10 percent by weight, more typically less than 5 percent by weight, although this is not a requirement.

Curable compositions according to the present disclosure may be dispensed/coated onto a substrate by any suitable method including, for example, screen printing, inkjet printing, flexographic printing, and stencil printing. Of these, inkjet printing (e.g., thermal inkjet printing or piezo inkjet printing) is particularly well-suited for use with the curable compositions according to the present disclosure. To be useful in inkjet printing techniques, preferably the curable composition is formulated to be solvent free, although organic solvent may be included. Inkjet printing may be carried out over a range of temperatures (e.g., 20° C. to 60° C.). Inkjet printable curable compositions should typically have a shear viscosity of less than about 100 centipoise, preferably less than 50 centipoise, more preferably less than 30 centipoise, and most preferably less than 20 centipoise at the printing temperature.

Curing may be accomplished/accelerated by heating (e.g., in an oven or by exposure to infrared radiation) and/or exposure to actinic radiation (e.g., ultraviolet and/or electromagnetic visible radiation), for example. Selection of sources of actinic radiation (e.g., xenon flash lamp, medium pressure mercury arc lamp) and exposure conditions is within the capability of those having ordinary skill in the art.

In some embodiments, curable compositions according to the present disclosure are formulated as inks (e.g., screen printing inks or inkjet printable inks) or other dispensable fluids that can be applied to substrates such as electronic displays and optical electronic components thereof, for example. Examples include Organic Light Emitting Diodes (OLEDs), Quantum Dot Light Emitting Diodes (QDLEDs), Micro Light Emitting Diodes (μLEDs), and Quantum Nanorod Electronic Devices (QNEDs). Advantageously, inkjet printable curable compositions according to the present disclosure are suitable for use with optical electronic components due to their balance of low dielectric constant and high refractive index.

Curable compositions according to the present disclosure can be disposed on a substrate and at least partially cured (e.g., cured to a C-stage) to provide an electronic article including an optical electronic component such as, for example, as OLED display.

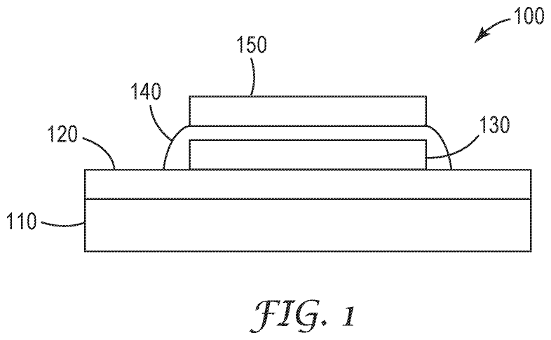

Referring now to FIG. 1, exemplary electronic device 100 comprises an optical electronic component in the form of OLED display 130 supported on Thin Film Transistor (TFT) 120 array on an OLED mother glass substrate 110. Thin Film Encapsulation (TFE) layer 140 comprises a cured composition according to the present disclosure composition 140 according to the present disclosure is disposed on and encapsulates OLED display 130. Touch sensor assembly (e.g., an On-Cell Touch Assembly (OCTA)) 150 is disposed on cured composition 140.

Due to the close proximity of the touch sensor and the OLED/TFT array, the electronic signals from the OLED display have a potential to interfere with the touch sensor (e.g., OCTA). Hence, the cured composition in the TFE requires a lower dielectric constant in order to electronically isolate the OCTA layer from the OLED and improve touch sensitivity in the device. If the dielectric constant of the cured composition is too large (e.g., >4 at 1 MHz), very thick layers of the TFE would be required to reach the low capacitance per unit area typical of capacitive touch sensors. Conversely, a low dielectric constant material (e.g., <3 at 1 MHz), permits the TFE layer to be only a few microns thick while still serving the function of electronic isolation between the OLED and the OCTA layers. Such thin TFE layers are also easier and faster to print than thicker layers, and have better overall optical properties.

Objects and advantages of this disclosure are further illustrated by the following non-limiting examples, but the particular materials and amounts thereof recited in these examples, as well as other conditions and details, should not be construed to unduly limit this disclosure.

### EXAMPLES

Unless otherwise noted, all parts, percentages, ratios, etc. in the Examples and the rest of the specification are by weight.

Table 1, below, lists materials used in the examples.

TABLE 1

| MATERIAL | SOURCE |
|---|---|
| 1,1,4,4-Tetramethyl-1,4-disilabutane (TMDSB) | Gelest, Inc., Morrisville, |
| | Pennsylvania |
| Tetravinylsilane, 95% (TVS) | Gelest, Inc. |
| Tetraallylsilane (TAS) | Gelest, Inc. |
| 1,3-Divinyltetraphenyldisiloxane | Gelest, Inc. |
| 1,4-Bisdimethylsilylbenzenne | Gelest, Inc. |
| 1,2-Bisdimethylsilylbenzene | Alfa Aesar, Ward Hill, |
| | Massachusetts |
| Bis(p-dimethylsilyl)phenyl ether | Gelest, Inc. |
| Tetrakis(dimethylsiloxy)silane | Gelest, Inc. |
| Platinum divinyltetramethyldisiloxane complex | Gelest, Inc. |
| (3.0% platinum in vinyl-terminated PDMS) | |
| Platinum(II) acetylacetonate, 97% (Pt acac) | MilliporeSigma, Saint |
| | Louis, Missouri |
| Dicumyl peroxide, 98% | MilliporeSigma |

### Example 1

### Preparation of Hyperbranched Polycarbosilane 1 (HB-PCS-1)

1,4-Bisdimethylsilylbenzene (9.20 g, 0.0473 mol) was added dropwise to a solution of tetravinylsilane (10.0 g, 0.0734 mol, 3.1 molar excess of vinyl) and platinum divinyltetramethyldisiloxane complex (1 drop) in toluene (50 mL). The reaction mixture was stirred at 60° C. for 3 days, and toluene and excess monomer was removed in vacuo to give the product as a viscous liquid. Gel Permeation Chromatography (GPC, toluene, ELSD): Mₙ=2500 g/mol, M_{w}=4900 g/mol, polydispersity=1.9. Differential Scanning calorimetry (DSC, 10° C. min⁻¹, N₂): −45° C. (T_{g}). Refractive index=1.538.

### Example 2

### Preparation of Hyperbranched Polycarbosilane 2 (HB-PCS-2)

1,4-Bisdimethylsilylbenzene (9.20 g, 0.0473 mol) was added dropwise to a solution of tetraallylsilane (14.12 g, 0.0734 mol, 3.1 molar excess of allyl) and platinum divinyltetramethyldisiloxane complex (1 drop) in toluene (50 mL). The reaction mixture was stirred at 60° C. for 2 days, and toluene was removed in vacuo. The crude product was washed with acetonitrile (3×20 mL) and dried, and the product was obtained as a viscous liquid. GPC (Toluene, ELSD): Mₙ=2700 g/mol, M_{w}=10,000 g/mol, polydispersity=3.7. DSC (10° C. min⁻¹, N₂): −75° C. (T_{g}). Refractive index=1.525.

### Example 3

### Preparation of Hyperbranched Polycarbosilane 3 (HB-PCS-3)

Bis-p-dimethylsilylphenyl ether (6.79 g, 0.0237 mol) was added dropwise to a solution of tetravinylsilane (5.0 g, 0.0367 mol, 3.1 molar excess of vinyl) and platinum divinyltetramethyldisiloxane complex (1 drop) in toluene (20 mL). The reaction mixture was stirred at 60° C. for 4 days, and toluene was removed in vacuo. The crude product was washed with acetonitrile (3×20 mL) and dried, and the product was obtained as a viscous liquid. GPC (Toluene, ELSD): Mₙ=2600 g/mol, M_{w}=7600 g/mol, polydispersity=2.9. DSC (10° C. min⁻¹, N₂): −19° C. (T_{g}). Refractive index=1.557.

### Example 4

### Preparation of Hyperbranched Polycarbosilane 4 (HB-PCS-4)

Bis-p-dimethylsilylphenyl ether (4.27 g, 0.0149 mol) was added dropwise to a solution of tetraallylsilane (4.44 g, 0.0231 mol, 3.1 molar excess of allyl) and platinum divinyltetramethyldisiloxane complex (1 drop) in toluene (20 mL). The reaction mixture was stirred at 70° C. for 3 days, and toluene and was removed in vacuo. The crude product was washed with acetonitrile (3×20 mL) and dried, and the product was obtained as a viscous liquid. GPC (Toluene, ELSD): Mₙ=3000 g/mol, M_{w}=18,000 g/mol, polydispersity=6.0. DSC (10° C. min⁻¹, N₂): −55° C. (T_{g}). Refractive index=1.544.

### Example 5

### Preparation of Hyperbranched Polycarbosilane 5 (HB-PCS-5)

1,2-Bisdimethylsilylbenzene (4.60 g, 0.0237 mol) was added dropwise to a solution of tetravinylsilane (5.0 g, 0.0367 mol, 3.1 molar excess of vinyl) and platinum divinyltetramethyldisiloxane complex (1 drop) in toluene (25 mL). The reaction mixture was stirred at 60° C. for 3 days, and toluene and was removed in vacuo. The crude product was washed with acetonitrile (3×20 mL) and dried, and the product was obtained as a viscous liquid. GPC (Toluene, ELSD): Mₙ<1500. DSC (10° C. min⁻¹, N₂): −67° C. (T_{g}). Refractive index=1.538.

### Example 6

### Preparation of Hyperbranched Polycarbosilane 6 (HB-PCS-6)

1,2-Bisdimethylsilylbenzene (5.33 g, 0.0274 mol) was added dropwise to a solution of tetraallylsilane (8.07 g, 0.042 mol, 3.1 molar excess of allyl) and platinum divinyltetramethyldisiloxane complex (1 drop) in toluene (25 mL). The reaction mixture was stirred at 60° C. for 5 days, and toluene was removed in vacuo. The crude product was washed with acetonitrile (3×20 mL) and dried, and the product was obtained as a viscous liquid. GPC (Toluene, ELSD): Mₙ=1000 g/mol, M_{w}=2600 g/mol, polydispersity=2.9. DSC (10° C. mind, N₂): −84° C. (T_{g}). Refractive index=1.520.

### Example 7

### Preparation of Hyperbranched Polycarbosiloxane 7 (HB-PCSOX-7)

Tetrakis(dimethylsiloxy)silane (0.61 g, 1.85 mmol) was added dropwise to a solution of 1,3-divinyltetraphenyldisiloxane (5.0 g, 0.0115 mol, 3.1 molar excess of vinyl) and platinum divinyltetramethyldisiloxane complex (1 drop, 2.1-2.4% Pt in xylene) in toluene (15 mL). The reaction mixture was stirred at 70° C. for 3 days, and toluene was removed in vacuo. Acetonitrile (20 mL) was added to the crude product and left to stand at room temperature for 24 hrs. A white solid precipitated out, the solution component was isolated, acetonitrile was removed in vacuo, and the product was obtained as a viscous liquid. GPC (Toluene, ELSD): Mₙ=1000 g/mol, M_{w}=1200 g/mol, polydispersity=1.2. DSC (10° C. min⁻¹, N₂): −40° C. (T_{g}). Refractive index=1.594.

### Test Methods

### Gel Permeation Chromatography (GPC)

Solutions of approximate concentration 1.5 mg/mL were prepared in toluene. The samples were swirled on an orbital shaker for 12 hrs. The sample solutions were filtered through 0.45 micron PTFE syringe filters and then analyzed by GPC. An Agilent (Santa Clara, California) 1260 LC instrument was used with an Agilent PLgel MIXED B+C column at 40° C., toluene eluent at 1.0 mL/min, a NIST polystyrene standard (SRM 705a), and an Agilent 1260 Evaporative Light Scattering Detector.

### Differential Scanning Calorimetry (DSC)

DSC samples were prepared for thermal analysis by weighing and loading the material into TA Instruments aluminum DSC sample pans. The specimens were analyzed using the TA Instruments Discovery Differential Scanning calorimeter (DSC-SN DSC1-0091) utilizing a heat-cool-heat method in standard mode (−155° C. to about 50° C. at 10° C./min.). After data collection, the thermal transitions were analyzed using the TA Universal Analysis program. The glass transition temperatures were evaluated using the step change in the standard heat flow (HF) curves. The midpoint (half height) temperature of the second heat transition is quoted.

### Measurement of Refractive Index

The refractive index was measured on a Milton Roy Company refractometer (model number: 334610). The liquid sample was sealed between two prisms and the refractive index was measured at 20° C. at the 589 nm line of a sodium lamp.

Dielectric Spectroscopy for Liquids at 100 kHz-1 MHz

Dielectric property and electrical conductivity measurements on liquids were performed with an Alpha-A High Temperature Broadband Dielectric Spectrometer modular measurement system from Novocontrol Technologies GmbH (Montabaur, Germany). A Keysight Model 16452A liquid dielectric test fixture was used to contain the liquid as a parallel plate capacitor. A ZG2 extension test interface for the Alpha-A modular measurement system was used to allow automated impedance measurements of the Keysight Model 16452A liquid dielectric test fixture through the Novocontrol software. The dielectric constants were computed from ratio of the capacitance of the test cell with liquid to the capacitance of the test cell with air. In order to measure the higher viscosity liquids with the 16452A test cell, the liquid was first heated to 50-55° C. and held at this temperature for 15-30 minutes. The liquid was next injected into the liquid test cell with a syringe. After injection, the liquid was allowed to settle for up to 30 minutes, in order to minimize and avoid formation of air bubbles. After 30 minutes settling, the sample was tested.

### Dielectric Constants of Formulation Components

The dielectric constants of hyperbranched polymers 1-4, 6 and TMDSB were measured at 20° C. at frequencies of 100 kilohertz (kHz) and 1 megahertz (MHz). Results are reported in Table 2, below.

TABLE 2

DIELECTRIC CONSTANT at 20° C.

| MATERIAL | 100 kHz | 1 MHz |
|---|---|---|
| TMDSB | 2.34 | 2.34 |
| HB-PCS-1 | 2.85 | 2.85 |
| HB-PCS-2 | 2.42 | 2.44 |
| HB-PCS-3 | 2.95 | 3.07 |
| HB-PCS-4 | 3.09 | 3.07 |
| HB-PCS-6 | 2.71 | 2.69 |

### Examples 8 to 17

Two-component 100% solids/solventless formulations (Examples 8-10 in Table 3) were cured by platinum-catalyzed hydrosilylation under various conditions to give hard transparent coatings. The formulations had a silane component with Si—H functionality (TMDSB) and a component with vinyl functionality (HB-PCS-1, 2 or 3). One-component 100% solids/solventless formulations (Examples 11-14 in Table 3) were peroxide cured to give hard transparent coatings.

TABLE 3

| EXAMPLE | HBP 1 | HBP 2 | HBP 3 | HBP 4 | HBP 5 | HBP 6 | HBP 7 | TMDSB |
|---|---|---|---|---|---|---|---|---|
| 8 | 85 | 0 | 0 | 0 | 0 | 0 | 0 | 15 |
| 9 | 0 | 85 | 0 | 0 | 0 | 0 | 0 | 15 |
| 10 | 0 | 0 | 85 | 0 | 0 | 0 | 0 | 15 |
| 11 | 100 | 0 | 0 | 0 | 0 | 0 | 0 | 0 |
| 12 | 0 | 100 | 0 | 0 | 0 | 0 | 0 | 0 |
| 13 | 0 | 0 | 100 | 0 | 0 | 0 | 0 | 0 |
| 14 | 0 | 0 | 0 | 100 | 0 | 0 | 0 | 0 |

Examples 8-10 were thermally cured by adding platinum divinyltetramethyldisiloxane complex (Karstedt's catalyst) such that the formulations had a content of 0.0015 wt. % platinum, depositing 0.25 mL of formulation onto a glass microscope slide via pipette, and heating at 100° C. for 5 mins.

Example 9 was also independently UV cured at room temperature by adding platinum(II) acetylacetonate (Pt acac) such that the formulation had a content of 0.01 wt. % platinum, depositing 0.25 mL of formulation onto a glass microscope slide via pipette, and curing using a Clearstone CF1000 UV LED system (395 nm, 100% intensity corresponding to 319 mW/cm² for 5 minutes at a distance of 1 cm from the surface of the sample).

Examples 11 to 14 were thermally cured by adding dicumyl peroxide at 2 wt. %, depositing 0.25 mL of formulation onto a glass microscope slide via pipette, and heating at 150° C. for 120 mins

### Refractive Indices of Formulations

The refractive indices of Examples 8-14 formulations were measured at 20° C. before cure. Results are reported in Table 4, below.

TABLE 4

| EXAMPLE | REFRACTIVE INDEX at 20° C. |
|---|---|
| 8 | 1.511 |
| 9 | 1.510 |
| 10 | 1.555 |
| 11 | 1.538 |
| 12 | 1.525 |
| 13 | 1.557 |
| 14 | 1.544 |

The preceding description, given in order to enable one of ordinary skill in the art to practice the claimed disclosure, is not to be construed as limiting the scope of the disclosure, which is defined by the claims and all equivalents thereto.

1. A hyperbranched polymer comprising a reaction product of components:
a) at least one first organosilane independently having p vinyl groups and consisting of C, H, Si, and optionally O atoms, wherein each p is independently an integer greater than or equal to 2;
b) at least one second organosilane independently having q Si—H groups and consisting of C, H, Si, and optionally O atoms, wherein each q is independently an integer greater than or equal to 2; and
c) at least one hydrosilylation reaction catalyst,
wherein p/q is at least 3.1, and
wherein components a) and b) combined contain 15 to 60 percent by weight of aromatic carbon atoms.

2. The hyperbranched polymer of claim 1, wherein p/q is at least 4.

3. The hyperbranched polymer of claim 1, wherein the aromatic carbon atoms are not present in component b).

4. The hyperbranched polymer of claim 1, wherein the aromatic carbon atoms are not present in component a).

5. The hyperbranched polymer of claim 1, wherein the aromatic carbon atoms are present in both of the components a) and b).

6. The hyperbranched polymer of claim 1, wherein the at least one second organosilane in component b) is independently represented by the formula
Z(SiR¹₂H)ₐ
wherein Z is an a-valent radical composed of Si and O or Z is an a-valent radical composed of C, H, and optionally O, wherein Z has from 1 to 12 carbon atoms, each R¹ is independently a hydrocarbyl group having from 1 to 12 carbon atoms, and a is an integer from 2 to 8.

7. The hyperbranched polymer of claim 1, wherein the at least one second organosilane in component b) is selected from the group consisting of H(CH₃)₂SiCH₂CH₂Si(CH₃)₂H, H(CH₃)₂SiC₆H₄Si(CH₃)₂H, H(CH₃)₂SiC₆H₄OC₆H₄Si(CH₃)₂H, Si(OSi(CH₃)₂H)₄, and combinations thereof.

8.-12. (canceled)

13. A method of making a hyperbranched polymer, the method comprising combining components:
a) at least one first organosilane independently having p vinyl groups and consisting of C, H, Si, and optionally O atoms, wherein each p is independently an integer greater than or equal to 2;
b) at least one second organosilane independently having q Si—H groups and consisting of C, H, Si, and optionally O atoms, wherein each q is independently an integer greater than or equal to 2; and
c) at least one hydrosilylation reaction catalyst,
wherein p/q is at least 3.1, and
wherein components a) and b) combined contain 15 to 60 percent by weight of aromatic carbon atoms.

14. The method of claim 13, wherein p/q is at least 4.

15. A curable composition comprising:
the hyperbranched polymer of claim 1; and
an effective amount of a crosslinker system.

16. The curable composition of claim 15, wherein the crosslinker system comprises a third organosilane having at least two Si—H groups and a hydrosilylation reaction catalyst.

17. The curable composition of claim 16, wherein the third organosilane has at least three Si—H groups.

18. The curable composition of claim 15, wherein the hydrosilylation reaction catalyst comprises a photohydrosilylation reaction catalyst.

19. The curable composition of claim 18, wherein the crosslinker system comprises at least one of a free-radical thermal initiator or a free-radical photoinitiator.

20. The curable composition of claim 15, wherein the curable composition has a refractive index of from 1.50 to 1.60.

21. The curable composition of claim 15, wherein the curable composition has a dielectric constant of less than 3.0 at a measurement frequency of 1 megahertz.

22. An at least partially cured curable composition according to claim 15.

23. An electronic article comprising an at least partially cured curable composition according to claim 15 disposed on an optical electronic component.

24. The electronic article of claim 23, wherein the optical component comprises at least one of an organic light emitting diode, a quantum dot light emitting diode, a micro light emitting diode, or a quantum nanorod electronic device.

25. The electronic article of claim 23, wherein the optical component comprises an organic light emitting diode.
